(19) United States
(12) Patent Application Publication
(10) Pub. No.: US 2008/0070378 A1
(43) Pub. Date: Mar. 20, 2008

(54) Dual laser separation of bonded wafers

(76) Inventor: Jong-Souk Yeo, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/523,170

(22) Filed: Sep. 19, 2006

(51) Int. Cl. H01L 21/00

(52) U.S. Cl. 438/460

(57) ABSTRACT

A system for dicing a bonded wafer includes a plurality of substrates having at least a first substrate bonded to at least a second substrate. A first laser is configured to emit a first laser beam at a first predetermined wavelength such that the first laser beam creates a modified layer within the first substrate and is transparent to the second substrate. A second laser is configured to emit a second laser beam at a second predetermined wavelength such that the second laser beam heats an inner portion of the second substrate creating a stress plane therein and is transparent to the first substrate.

### BACKGROUND

Electronic components in televisions, projection systems, and other optical devices are often fabricated from bonded semiconductor wafers that generally include at least one semiconductor substrate bonded to at least one top glass layer. In some cases, the semiconductor substrate may also include microelectromechanical system (MEMS) devices, which are microscopic mechanical devices fabricated using integrated circuit manufacturing technologies. This allows two or three dimensional mechanical systems to be created in the same small area typical of an integrated circuit. In this way, thousands of MEMS devices can be fabricated onto a single wafer.

Fabricating a bonded wafer for use in electronic applications generally includes separating or dicing the individual MEMS devices into usable portions commonly referred to as chips or dies. One known method for dicing bonded wafers includes cutting the wafer using mechanical blades. Although this method is effective for separating the wafer into dies, the thickness of the mechanical blades used to cut the wafers causes an undue loss of wafer material, which is generally referred to as “kerf” loss. Kerf loss is particularly inconvenient in the production of increasingly smaller dies, as a greater amount of the wafer material relative to the overall wafer size is lost during the dicing operation, thus requiring larger wafers to account for the lost material. Additionally, kerf loss may cause uneven or jagged surfaces along the diced edges of the dies. Cutting processes using mechanical blades can also cause vibration within the wafers during the dicing process, which can disturb or break the MEMS devices contained therein and/or the bonds between the glass layer and semiconductor substrate.

Another known method for dicing bonded wafers includes a laser ablation process, which employs a high-powered laser to burn away wafer material along a desired cutting path to completely separate the undiced wafer into dies. Although an effective dicing technique, the laser ablation process causes kerf loss and creates excess debris on the diced wafer portions, which must be cleaned prior to further processing. In addition, laser ablation creates residual stresses within the wafer, which can further decrease wafer quality and durability.

Finally, the accuracy of known cutting and laser ablation processes deteriorates rapidly as the speed of the dicing operation is increased or the thickness of the wafer is increased, which limits production capabilities in a mass manufacturing environment.

Accordingly, the embodiments described hereinafter were developed in light of these and other drawbacks associated with fabricating bonded wafers.

### BRIEF DESCRIPTION OF THE DRAWINGS

The present embodiments will now be described, by way of example, with reference to the accompanying drawings, in which:

FIG. 1 illustrates an exemplary dual laser dicing system according to an embodiment;

FIG. 2 illustrates an exemplary process for dicing a bonded wafer according to an embodiment; and

FIGS. 3A-3F each illustrate exemplary steps according to the process of FIG. 2.

### DETAILED DESCRIPTION

### Introduction

A system and method are provided for dicing bonded wafers having a first substrate bonded to a second substrate. The system generally includes a first laser and a second laser, wherein the first laser is configured to emit a laser beam that creates a modification layer within the first substrate, without altering the structure of the second substrate. Similarly, the second laser is configured to emit a laser beam that heats an inner portion of the second substrate to create stresses along a desired dicing path in the second substrate, without altering the structure of the first substrate. In this way, the first and second lasers are configured to emit laser beams that are specifically tailored to materially alter one of either the first or second substrate, while being transparent to the other.

In one embodiment, the system further includes a cooling unit that cools the inner portion of the second substrate after being heated by the second laser. The cooling unit localizes stresses created within the second substrate by the second laser. In another embodiment, the system includes a separator, such as a roller, which applies a force to the wafer to precisely break apart the wafer along a desired dicing path.

### System Overview

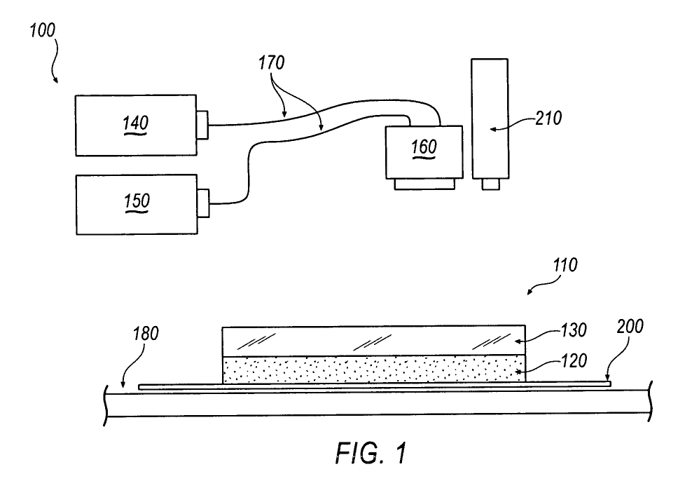

FIG. 1 illustrates an exemplary dual laser dicing system 100 for dicing a bonded semiconductor wafer 110, which generally includes a semiconductor substrate 120 bonded to a glass layer 130. Semiconductor substrate 120 may include any suitable semiconductor material including, but not limited to, silicon (Si), Gallium Arsenide (GaAs), and Indium Phosphide (InP). In alternative configurations, wafer 110 may include a plurality of semiconductor substrates that are alternately bonded to a plurality of glass layers (not shown). For example, one embodiment of wafer 110 may include a semiconductor substrate that is sandwiched between two glass layers. One of ordinary skill in the art understands that wafer 110 may include any number of semiconductor substrates bonded to glass layers in any configuration. Wafer 110 may further include a plurality of microelectromechanical system (MEMS) devices (not shown) incorporated within semiconductor substrate 120. Additionally, wafer 110 may include trenches (not shown) in either the semiconductor substrate 120 or the glass layer 130 to guide the mechanics of the dicing process.

Dicing system 100 includes first and second lasers 140, 150, which selectively emit laser beams at predetermined wavelengths to a beam modulator 160 through a set of optics 170. In one embodiment, modulator 160 is a galvanometer scanning head that uses an electromechanical transducer to deflect and control laser beams from the first and second lasers 140, 150 to the wafer 110. Using a galvanometer, the laser beams from the first and second lasers 140, 150 are transmitted by optics 170 to either a single scanning head, or side-by-side scanning heads. In either case, the laser beams are deflected and controlled within the galvanometer using internal mirrors. When using side-by-side scanning heads, each of the laser beams from the first and second lasers 140, 150 are deflected and controlled using separate mirrors with coatings that are optimized to deflect only the predetermined wavelength from each of the respective lasers 140, 150. When using a single scanning head, there is a single mirror having a stack of multiple reflective coatings, each of which are optimized to deflect and control both of the predetermined wavelengths from each of the respective lasers 140, 150. In other embodiments, modulator 160 may include mirrors, either alone or in combination with other scanning and control devices, which are suitable for deflecting and controlling each of the laser beams from the first and second lasers 140, 150.

The optics 170 that transmit the laser beams from the first and second lasers 140, 150 to modulator 160 may include spatial optics (e.g., dielectric mirrors, metallic mirrors or polarizers), guided optics (e.g., fibers or fiber bundles), or any other optics device that is suitable for transmitting laser beams from the first and second lasers 140, 150 to modulator 160.

First laser 140 is configured to emit laser beams at a predetermined wavelength such that the laser beams create a modified region or layer within semiconductor substrate 120 along a desired dicing path without affecting the structure of glass layer 130. In one embodiment, first laser 140 operates at a wavelength of approximately 1064 nanometers. However, one of skill in the art understands that first laser 140 may operate at any wavelength, wherein first laser 140 forms a modified region within semiconductor substrate 120 while not affecting the structure of glass layer 130.

The formation of a modified region or layer in the semiconductor substrate 120 alters the structure thereof to provide a preferential cleavage plane that guides the eventual separation of wafer 110. Specifically, first laser 140 heats or melts an inner region of semiconductor substrate 120 thereby forming a preferential cleavage plane. Despite the formation of a modified layer, the semiconductor substrate 120 remains substantially intact after the application of first laser 140. This is in part due to the fact that the first laser 140 creates only a modified region or layer within the substrate 120, which guides the eventual separation of the wafer into individual dies rather than completely separating the substrate 120 upon application of the first laser 140. In addition, the structure of the semiconductor substrate 120 is further supported by glass layer 130, which is unaffected by the predetermined wavelength of the first laser 140 and remains completely intact and unaltered. Finally, as shown in FIG. 1, wafer 110 is secured to staging area 180 by tape layer 200, which holds the semiconductor substrate 120 and the glass layer 130 in position until after the final separation of the dies is completed.

Second laser 150 is configured to emit laser beams at a predetermined wavelength and focal length, such that the laser beams heat an inner portion of the glass layer 130 without affecting the structure of semiconductor substrate 120. In one embodiment, second laser 150 operates at a wavelength of approximately 10.6 micrometers. However, one of ordinary skill in the art understands that second laser 150 may operate at any wavelength wherein the second laser 150 can heat an inner portion of glass layer 130 without altering the structure of semiconductor substrate 120. The inner portion of glass layer 130 is subsequently cooled by a cooling unit 210 to form a stress concentrated plane at the inner portion of glass layer 130 within or in the vicinity of the inner portion. Cooling unit 210 may cool the inner regions of glass layer 130 with a stream of water, carbon dioxide gas, ethanol, compressed dry air, or any other known cooling method. In general, cooling unit 210 cools the inner region of glass layer 130 immediately after second laser 150 heats the inner region. Cooling unit 210 thereby localizes stresses along the inner portion which are initiated by second laser 150. The cooling of the glass layer 130 after the application of the second laser 150 further weakens the inner portion of the glass layer 130 to promote the precise separation of wafer 110 into dies. Despite the weakening and/or formation of stress concentrated planes within glass layer 130, glass layer 130 will generally remain in one piece. As with the semiconductor substrate 120 described above, because the second laser 150 only forms a structurally modified plane rather than completely separating the glass, the glass layer 130 remains substantially intact after the application of the second laser 150. In addition, the entire wafer 110 is held in place by tape layer 200.

Alternatively, or in combination with the control of modulator 160, stage 180 may be moved vertically and/or horizontally to control the position of the laser beams along the desired dicing path. In this way, the movement of stage 180 is used for coarse adjustments (i.e., larger movements of wafer 110), while the modulator 160 is used for fine adjustments (i.e., smaller movements of wafer 110) such as focusing and scanning functions.

System 100 may also include a separator, such as a roller (not shown in FIG. 1), which applies an external force to the surface of the wafer 110 after the application of the first and second lasers 140, 150, thereby breaking apart both the semiconductor substrate 120 and the glass layer 130. The roller provides a force which breaks the semiconductor substrate 120 and glass layer 130 at a point that generally coincides with the weakened modified layer and the inner portion, respectively, thereby dicing wafer 110 into a plurality of dies.

### Exemplary Process

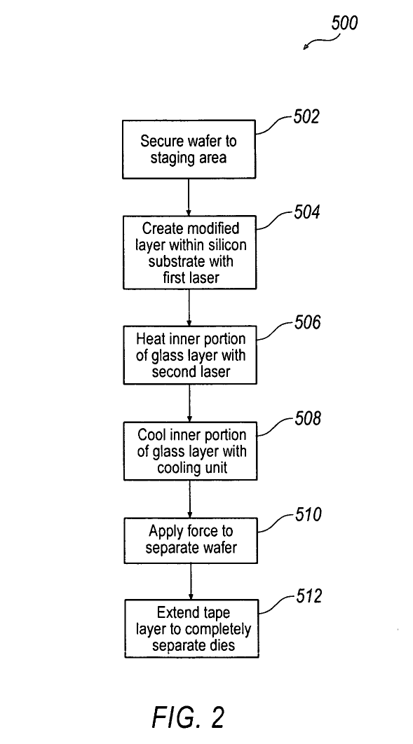

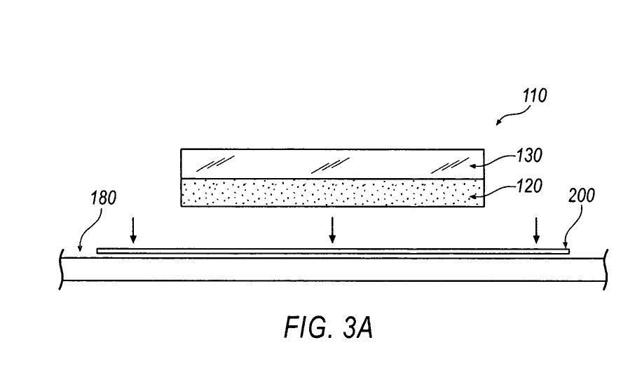

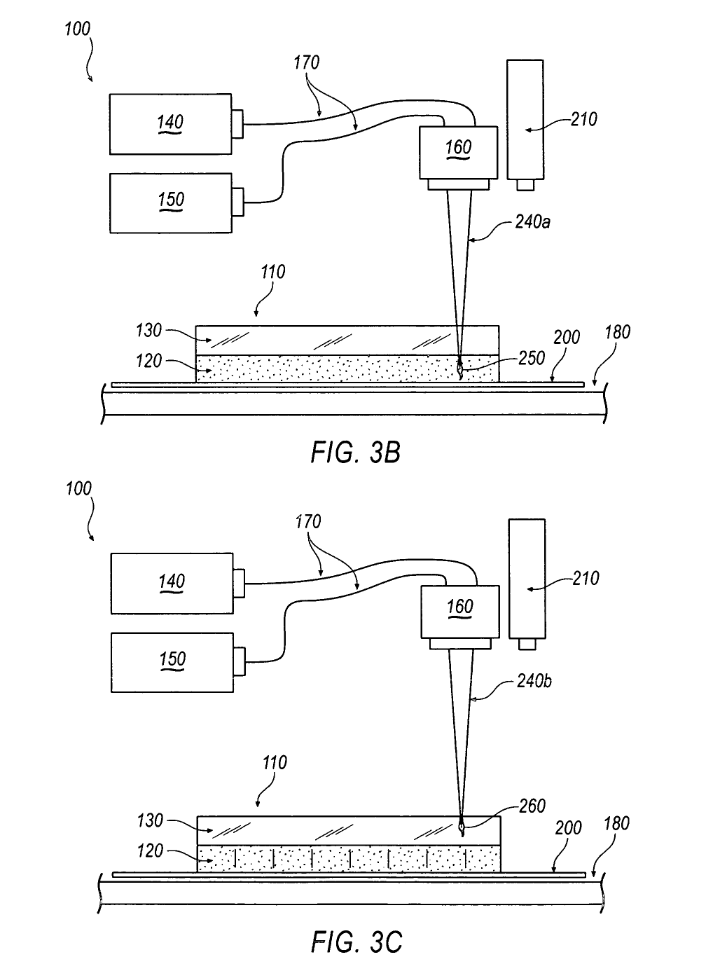

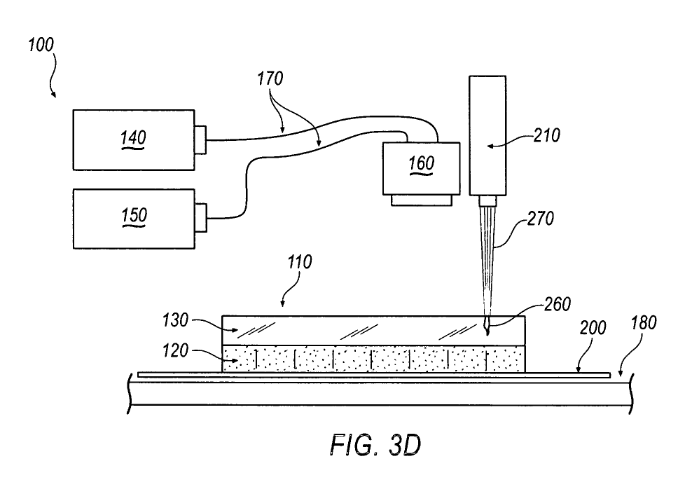

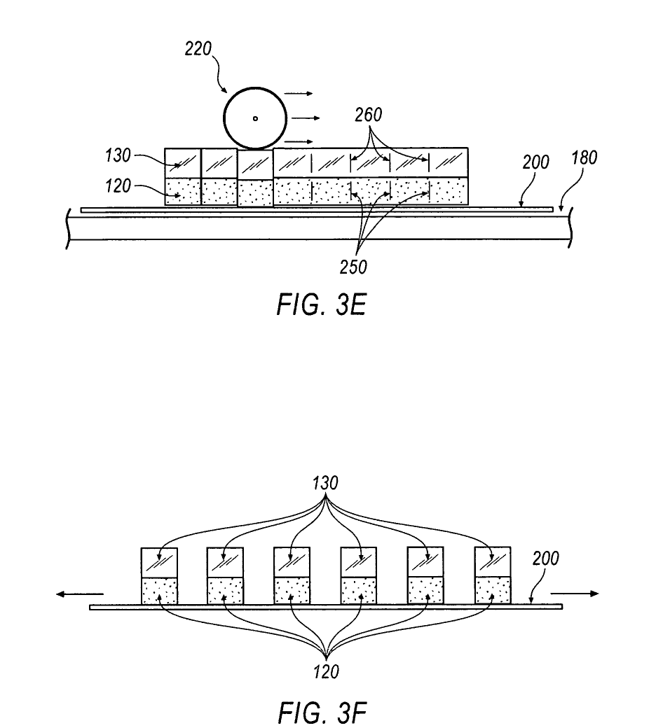

FIGS. 2 and 3A-3E illustrates an exemplary process 500 for dicing a bonded wafer 110. Referring first to FIG. 3A, at step 502, semiconductor substrate 120 is secured to stage 180 by tape layer 200. Tape layer 200 is generally provided with a high-friction surface to prevent wafer 110 from slipping relative to tape layer 200 during the dicing process. As shown in FIG. 3B, first laser 140 at step 504 emits a laser beam 240a to modulator 160 through optics 170 and creates a modified layer 250 within semiconductor substrate 120. Modified layer 250 represents an inner portion of semiconductor substrate 120, which provides a preferential cleavage plane as a result of heating or melting as initiated by first laser 140, as described above. Modulator 160 is configured to focus the depth of laser beam 240a to any depth within semiconductor substrate 120 that is suitable for creating modified layer 250 along a desired dicing path.

As shown in FIG. 3C, at step 506 second laser 150 emits laser beam 240b to modulator 160 through optics 170, which heats an inner portion 260 of glass layer 130. Second laser 150 heats inner portion 260 during or after the operation of first laser 140, as described above. In one embodiment, second laser 150 operates at approximately the same time as first laser 140 to enhance the speed with which wafer 110 can be diced. In this case, modulator 160 generally includes a single dual coated mirror for reflecting the laser beams emitted by first laser 140 and second laser 150. However, the same functionality can be achieved using a multiple mirror approach. Modulator 160 is configured to focus laser beam 240b to any desired depth of glass layer 130 that is suitable for creating a stress plane along the desired dicing path.

Referring now to FIG. 3D, at step 508 cooling unit 210 cools the inner portion 260 of glass layer 130. In one embodiment, cooling unit 210 cools inner portion 260 of glass layer 130 immediately after inner portion 260 is heated in step 506. In some cases, steps 506 and 508 are combined such that cooling unit 210 cools inner portion 260 as modulator 160 scans second laser 150 along wafer 110. In this way, inner portion 260 is cooled immediately after it is heated as modulator 160 scans laser beam 240b along wafer 110. Cooling unit 210 uses a stream 270 of carbon-dioxide gas that targets the inner portion 260 of glass layer 130. Alternatively, cooling unit 210 may provide a stream of water, ethanol, compressed dry air, or other generally known coolant to rapidly cool inner portion 260.

At step 510, and as shown in FIG. 3E, a force is applied to wafer 110 using a roller 220 that separates wafer 110 into individual dies. The force from the roller is such that wafer 110 is diced at inner portion 260 of glass layer 130 and modified layer 250 of semiconductor substrate 120. This separates wafer 110 into dies along the desired dicing pattern, which generally coincides with inner portion 260 of glass layer 130 and modified layer 250 of semiconductor substrate 120. One of ordinary skill in the art will recognize that other means of applying the force may be employed, such as, for example, expanding tape layer 200 as further described below in step 512. Additionally, trenches may be provided in wafer 110 along the dicing path to further guide the mechanics of the dicing process, and promote the accurate separation of the wafers into dies. And finally, FIG. 3F illustrates tape layer 200 being expanded at step 512 to separate the diced portions of wafer 110 apart from one another. Tape layer 200 therefore provides a means for securing wafer 110 during the dicing process, while also allowing for convenient separation and access to the diced wafers after the dicing process is completed.

Because no debris is created during the creation of modified layer 250 of semiconductor substrate 120 or the heating of inner portion 260 of glass layer 130, cleaning operations are not necessary. Additionally, kerf loss is virtually eliminated, enabling increased accuracy of the dicing process overall and a greater yield from each undiced wafer. Further, the accuracy of the dicing process does not significantly degrade as speed increases. For example, dual laser dicing system 100 may be operated at scanning speeds of up to 300 millimeters per second without a significant loss in quality.

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain embodiments, and should in no way be construed so as to limit the claimed invention.

In general, the foregoing description is intended to be illustrative and not restrictive. Many embodiments and applications other than the examples provided would be apparent to those of skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In sum, it should be understood that the invention is capable of modification and variation and is limited only by the following claims.

What is claimed is:

1. A system for dicing a bonded wafer comprising:
a plurality of substrates including at least a first substrate bonded to at least a second substrate;
a first laser configured to emit a first laser beam at a first predetermined wavelength, said first laser beam creates a modified layer within said first substrate and is transparent to said second substrate; and
a second laser configured to emit a second laser beam at a second predetermined wavelength, said second laser beam heats an inner portion of said second substrate creating a stress plane therein and is transparent to said first substrate.

2. The system of claim 1, further comprising a cooling unit configured to cool said inner portion of said second substrate to localize said stress plane.

3. The system of claim 1, wherein said modified layer forms a preferential cleavage plane within said first substrate.

4. The system of claim 1, further comprising a separator operable to apply a force to said first and second substrates, thereby separating the wafer along said modified layer and said inner portion.

5. The system of claim 4, wherein said separator is a roller.

6. The system of claim 4, wherein said separator comprises an extendable tape layer.

7. The system of claim 1, wherein said first substrate is a semiconductor substrate.

8. The system of claim 1, wherein said second substrate is a glass material.

9. The system of claim 1, wherein said first predetermined wavelength is approximately 1064 nanometers.

10. The system of claim 1, wherein said second predetermined wavelength is approximately 10.6 micrometers.

11. The system of claim 1, further comprising at least one modulator configured to deflect and control said first and said second laser beams.

12. The system of claim 11, wherein said at least one modulator is a galvanometer scan head.

13. The system of claim 1, wherein said plurality of substrates includes at least a third substrate bonded to said second substrate and wherein said third substrate is transparent to one of either said first or second predetermined wavelengths.

14. The system of claim 13, wherein said plurality of substrates includes at least a fourth substrate bonded to said third substrate and wherein said third substrate is transparent to said second predetermined wavelength and said fourth substrate is transparent to said first predetermined wavelength.

15. An apparatus for dicing a bonded wafer comprising:
a first laser configured to emit a first laser beam at a predetermined wavelength;
a second laser configured to emit a second laser beam at a second predetermined wavelength;
at least one modulator in communication with said first and second lasers and configured to receive said first and second laser beams;
wherein said first laser beam creates a modified layer within said first substrate and is transparent to said second substrate and wherein said second laser beam heats an inner portion of said second substrate creating a stress plane therein and is transparent to said first substrate.

16. The apparatus of claim 15, further comprising a cooling unit operable to cool said inner portion of said second substrate, thereby propagating a localized stress within said second substrate.

17. The apparatus of claim 15, wherein said modified layer forms a preferential cleavage plane within said first substrate.

18. The apparatus of claim 17, further comprising a separator operable to apply a force to said first and second substrates, thereby separating the wafer along said stress and cleavage planes.

19. The apparatus of claim 15, wherein said first predetermined wavelength is about 1064 nanometers.

20. The apparatus of claim 15, wherein said second predetermined wavelength is about 10.6 micrometers.

21. The apparatus of claim 15, wherein said at least one modulator is a galvanometer scan head.

22. The apparatus of claim 15, wherein said first predetermined wavelength of said first laser beam creates a modified layer within a third substrate bonded to said second substrate, and wherein said third substrate is transparent to said second predetermined wavelength.

23. The apparatus of claim 22, wherein said second predetermined wavelength of said second laser beam creates a stress plane in a fourth substrate bonded to said third substrate, and wherein said third substrate is transparent to said second predetermined wavelength and said fourth substrate is transparent to said first predetermined wavelength.

24. A system for dicing a bonded wafer comprising:
a means for forming a modified layer within at least a first substrate of the bonded wafer;
a means for forming a stress plane within at least a second substrate of the bonded wafer;
wherein said first substrate is unaffected by said means for forming a stress plane in said second substrate and said second substrate is unaffected by said means for forming a modified layer in said first substrate.

25. The system of claim 24, further comprising a means for cooling said inner portion of the second substrate to propagate a concentrated stress at said inner portion of the second substrate.

26. The system of claim 24, further comprising a means for separating the bonded wafer into individual dies along a dicing path formed by said stress plane and said modified layer.

27. The system of claim 24, further comprising a means for controlling the position of said first and said second laser beams.
